(19) United States
(12) Patent Application Publication
(10) Pub. No.: US 2007/0127534 A1
(43) Pub. Date: Jun. 7, 2007

(54) Complex optical device

(76) Inventors: Tomonori Shimamura, Tokyo (JP); Munechika Kubota, Tokyo (JP); Koji Yamada, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/633,491

(22) Filed: Dec. 5, 2006

(30) Foreign Application Priority Data
Dec. 6, 2005 (JP) 2005-351804

(51) Int. Cl. H01S 3/10; H01S 5/00

(52) U.S. Cl. 372/50.1; 372/46.015; 372/26

(57) ABSTRACT

The present invention provides a complex optical device capable of decreasing electric power consumption, generating a high quality laser, and modulating the laser without degradation. The complex optical device includes a laser diode element (LD) and an electroabsorption modulator element (EAM) which are formed on the same substrate and optically coupled with each other. Both of the LD and the EAM are formed from a semiconductive upper cladding layer having a first conductive type, an insulating core layer, and a semiconductive lower cladding layer having a second conductive type opposite to the first conductive type. The electrical isolation layer extending through the core layer from the surface of the upper cladding layer up to the surface of the substrate is formed by an ion injection at an area between the LD and the EAM to isolate the LD and the EAM electrically. The ion injection does not optically have an influence on the insulating core layer through which the LD and the EAM are optically coupled with each other.

### BACKGROUND OF THE INVENTION

1. Field of the Invention

The present invention relates to a complex optical device including a laser diode element (LD) and an electroabsorption modulator element (EAM) which are integrally fabricated on a substrate and optically coupled with each other.

2. Description of the Related Art

A complex optical device including an LD and an EAM which are integrated with each other on the same substrate is used as a light source having an electro-optical converting function in a high-speed optical communication system. The device has an operating frequency of 2.5 Gbps on greater. A conventional complex optical device having the LD and the EAM integrated with each other on the same substrate requires two different types of power supply voltages: a positive power supply voltage for the LD and a negative power supply voltage for the EAM. For instance, it is necessary to apply a power supply voltage of about +1.7 volts to an anode of the LD to generate a laser beam if cathodes of the LD and the EAM are formed on the same substrate. On the other hand, it is necessary to apply a modulating signal of about −0.5 to −2.5 volts to an anode of the EAM to control a transmission of the laser beam. Therefore, a method for operating with a single polarity power supply has been required with a view to decrease power consumption of the device in addition to simplification of a power supply circuit.

Conventional complex optical devices operating with a single power supply, for example, are disclosed by Japanese Patent Application No. H09-51142 and Japanese Patent Application, No. 2003-298175 (D1).

FIG. 1 is an equivalent circuit diagram showing the conventional complex optical device operating with a single-voltage source disclosed by D1. This optical device is provided with an LD and an EAM which are formed from PN junctions. The PN junctions of the LD and EAM elements, which are provided on the same substrate, correspond to a diode LD1a and a diode EAM1b. The PN junctions are connected in parallel to each other. Cathodes of the diode LD1a and the diode EAM1b are connected to a terminal 2 through which a common reference potential Vcm is supplied.

An anode of the diode LD1a is connected to a terminal 3 through which a power supply voltage Vcc is supplied. A capacitor C for noise reduction is connected across the anode and the cathode of the diode LD1a.

One of the terminals of a transmission line 4 are connected to an anode of the diode EAM1b and the other terminals are connected to a bias circuit 5, respectively. The Bias circuit 5 is provided with an inductor 5a through which a ground potential GND is supplied and a capacitor 5b through which a modulating signal Smod is supplied. A resistance 6 for matching an impedance of the transmission line 4 is connected across the anode and the cathode of the diode EAM1b.

In this complex optical device, the reference potential Vcm of the terminal 2 is set at a potential between the ground potential GND and the power supply voltage Vcc. A voltage Vcc −Vcm is applied to the diode LD1a in the forward directions and Vcm is applied to the diode EAM1b in the backward direction. Accordingly, the conventional complex optical device 1 can be operated in a single power supply.

However, the conventional complex optical device encounters the following problems:

The power supply voltage Vcc is required for operating the LD and operating the EAM. If +1.7 volts and −1.5 volts, for example, are applied to the diode LD1a and the diode EAM1b, respectively, a power supplied voltage of 4.3 volts is required for the operation. A modulating signal Smod of about ±1 volts is additionally necessary, so that a maximum power supply voltage of about 5.3 volts is necessary. Therefore, there arises a problem of power consumption. Since fluctuations in the reference potential Vcm at the terminal 2 is accompanied by fluctuations in the electrical potential at the anode of the EAM1b due to the modulating signal Smod, there is a possibility that the fluctuation of the reference potential Vcm will cause degradation of the laser beam.

On the other hand, methods for improving an optical coupling between an LD and an EAM which are fabricated on the same substrate are disclosed by Japanese Patent Application No. H10-326942 and Japanese Patent Application No. H10-326942. According to the complex optical devices produced by these methods, the LD region and the EAM region are not electrically isolated from each other, so that the above-mentioned problems arise.

### SUMMARY OF THE INVENTION

An object of the present invention is to provide a complex optical device that can reduce power consumption and can generate a light having a high quality waveform.

According to the present invention, there is provided a complex optical device having a laser emitting element and a laser modulation element which are formed on a substrate and optically coupled with each other. The complex optical device is provided with an electrical insulating layer formed between the laser emitting element and the laser modulation element. The laser emitting element has a first core layer and a first and a second semiconductive layers both of which sandwich the first core layer. The laser modulation element has a second core layer continuous to the first core layer via an intermediate core layer extending through the electrical insulating layer and a third and a fourth semiconductive layers both of which sandwich the second core layer.

According to a first aspect of the present invention, the LD and the EAM which are formed on the same substrate are electrically isolated from each other by the substrate and the isolation region whereas they are optically coupled with each other. A cathode of the LD and an anode of the EAM can be electrically connected to a ground potential. A positive power supply voltage can be supplied to the anode of the LD, and a positive modulating signal can be supplied to the cathode of the EAM. Since the power supply voltage supplied to the LD is not affected by fluctuations of the modulating signal, the complex optical device according to the present invention can generate and modulate a light having a high quality waveform. In addition, voltages supplied to the LD and the EAM are positive, with the effect that electric power consumption can be reduced by lowering a maximum voltage supplied to a power supply circuit.

### BRIEF DESCRIPTION OF THE DRAWINGS

FIG. 1 is a circuit diagram showing a conventional complex optical device;

FIG. 2A is a perspective view showing a complex optical device according to a first embodiment of the present invention;

FIG. 2B is a cross-sectional side view of FIG. 2 A taken along a line A1-A2;

FIG. 3 is a circuit diagram including an equivalent circuit of the complex optical device of FIG. 2A and 2B;

FIG. 4A is a cross-sectional side view showing a complex optical device of a second embodiment;

FIG. 4B is an equivalent circuit diagram showing the optical semiconductor device of FIG. 4A.

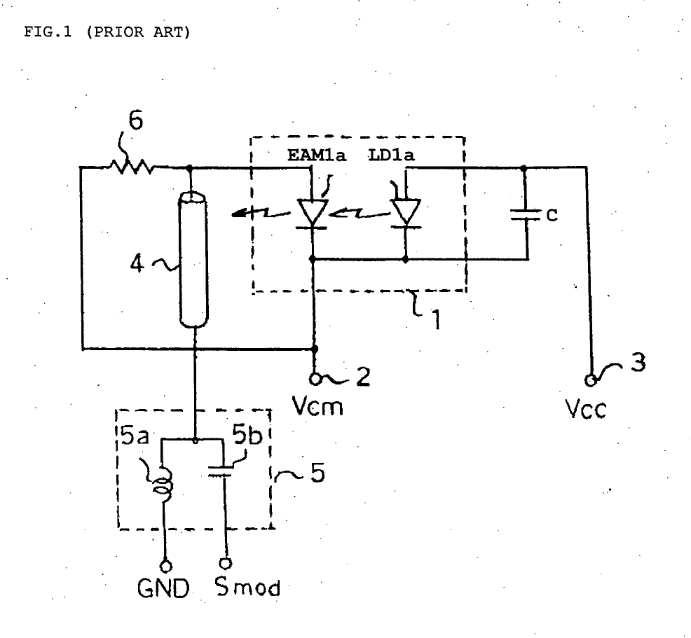

### DETAILED DESCRIPTION OF THE EMBODIMENTS

A complex optical device according to the present invention is provided with an LD and an EAM which are formed on the same substrate and optically coupled with each other. The complex optical device is further provided with an insulating layer formed between the LD and the EAM. The LD has a first core layer (insulating layer), a first semiconductive layer (n-type semiconductive layer), and a second semiconductive layer (p-type semiconductive layer). Both of the first and the second semiconductive layers sandwich the first core layer. The EAM has a second core layer (insulating layer) continuous to the first core layer via an intermediate core layer extending through the electrical insulating layer, a third semiconductive layer (n-type semiconductive layer), and a fourth semiconductive layer (p-type semiconductive layer). Both of the third semiconductive layer and the fourth semiconductive layer sandwich the second core layer. The electrical insulating layer extending through the intermediate core layer up to a surface of the substrate is formed by an ion injection at a central area between the LD and the EAM, thus electrically isolating the LD and the EAM. The first core layer of the EA modulator and the second core layer of the LD modulator are continuous to each other via intermediate core layer of the insulating layer, so that the LD and EAM are optically coupled with each other.

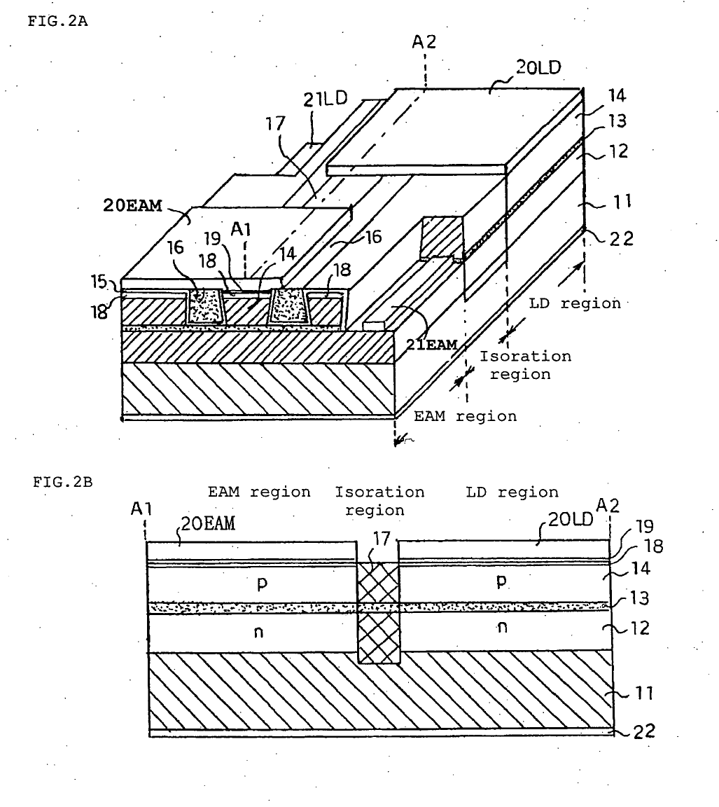

FIG. 2A is a perspective view showing a complex optical device according to a first embodiment of the present invention. FIG. 2B is a cross-sectional side view of FIG. 2 A taken along a line A1-A2.

As shown in FIG. 2A, a complex optical device is provided with a lower cladding layer 12, a core layer 13, and an upper cladding layer 14 which are sequentially provided on the same semiconductor substrate 11. The semiconductor substrate 11, for example, comprises InP that dose not contain impurities.

The lower cladding layer 12 and the upper cladding layers 14, for example, comprise n-type InP and p-type InP, respectively. The core layer 13, for example, comprises InGaAsP. This core layer 13 has a larger optical reflectance than the lower cladding layer 12 and the upper cladding layer 14.

In parallel with the A1-A2 line, the upper cladding layer 14 is provided with a ridge structure which is sandwiched between two grooves. The two grooves, which have bottoms contacting a surface of the core layer 13, are provided in the upper cladding layer 14 in parallel with the A1-A2 line shown in FIG. 2A. The grooves are coated with an insulating protective coating 15 comprising SiO₂ on an inside wall surface thereof and are filled with polyimide layers 16 having a small optical reflectance. The ridge structure of the upper cladding layer 14 is employed for lateral confinement of a laser beam.

The upper cladding layer 14 and the lower cladding layer 12 are composed of semiconductive layers which contain p-type and n-type impurities, respectively. The core layer 13 is an insulating layer that does not contain impurities. The PIN junctions of the LD region and the EAM region both of which are formed from the upper cladding layer 14 (p-type semiconductive layer), the core layer 13 (insulating layer), and the lower cladding layer 12 (n-type semiconductive layer) are represented as PIN structure diodes.

The PIN structure diodes of the EAM region and the LD region are isolated from each other by an isolation region as shown in FIG. 2A. Between the EAM region and the LD region shown at a left side and a right side of FIG. 2B, respectively, the isolation region is provided with an insulating layer 17 which extends through the core layer 13 and lower cladding layer from a surface of the upper cladding layer 14 up to an inner portion of the semiconductor substrate 11, thus islating the EAM region and LD region. The EAM region and the LD region are electrically isolated by the isolation region including the insulating layer 17. On the other hand, the EAM region and the LD region are optically coupled with each other through the core layer 13.

The upper cladding layer 14 of the EAM and the LD regions correspond to anodes of the EAM and the LD, respectively. Semiconductor contact layers 18 and ohmic electrodes 19 are sequentially formed on the surface of upper cladding layer 14 of the EAM region and the LD region. On the ohmic electrodes 19, an anode electrode 20EAM for wiring the EAM and an anode electrode 20LD for wiring the LD are formed.

The lower cladding layer 12 of the EAM and the LD regions correspond to cathodes of the EAM and the LD, respectively. A cathode electrode 21EA for wiring the EAM and a cathode electrode 21LD for wiring the LD are formed on the lower cladding layer 12 of the EAM and LD regions, respectively. A metallic film 22 for die bonding is formed under the semiconductor substrate 11.

Methods (1) and (2) for fabricating the isolation region of the first embodiment include the following steps:
(1) In a first step, the semiconductor substrate 11 is prepared. In a second step, the lower cladding layer 12 (n-type semiconductive layer) is formed on the semiconductor substrate 11. In a third step, the core layer 13 is formed on the lower cladding layer 12. In a fourth step, the upper cladding layer 14 (p-type semiconductive layer) is formed on the core layer 13. In a fifth step, a light element ion such as a proton and a boron ion etc. is injected at a central area of the upper cladding layer 14. The insulating layer 17 extending through the core layer 13 from the surface of the upper cladding layer 14 up to the semiconductor substrate 11 is formed, thus electrically isolating the LD region and the EAM region both of which sandwich the insulating layer 17. The insulating layer 17 may extend to an internal of the semiconductor substrate 11.
(2) In a first step, the semiconductor substrate 11 is prepared. In a second step, the lower cladding layer 12 (n-type semiconductive layer) is formed on the semiconductor substrate 11. In a third step, the core layer 13 is formed on the lower cladding layer 12. In a fourth step, a light element ion such as a proton and a boron ion etc. is injected at a central area of the core layer 13 so that a lower insulating layer extending through the core layer 13 from the surface of the lower cladding layer 12 up to the surface of the semiconductor substrate 11 is formed. In a fifth step, the upper cladding layer 14 (p-type semiconductive layer) is formed on the core layer 13. In a sixth step, a light element ion such as a proton and a boron ion etc. is injected at a central area of the upper cladding layer 14 so that an upper insulating layer extending from the surface of the upper cladding layer 14 up to the surface of the core layer 13 is formed. The insulating layer 17 including the lower insulating layer and the upper insulating layer is formed, thus isolating the LD region and the EAM region both of which sandwich the insulating layer 17. The insulating layer 17 may extend to an internal part of the semiconductor substrate 11.

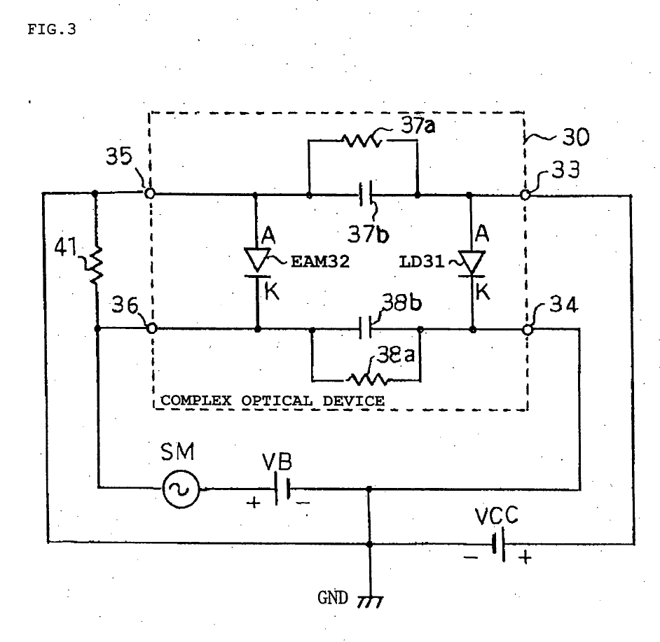

FIG. 3 is a circuit diagram including an equivalent circuit of the complex optical device of the first embodiment shown in FIGS. 2A and 2B. The optical device shown in FIGS. 2A and 2B is represented as an equivalent circuit surround by a dashed flame in FIG. 3. Four terminals of the equivalent circuit are connected to a power supply circuit. An operation of the first embodiment will be described while referring to FIG. 3.

A complex optical device 30 surrounded by a dashed flame in FIG. 3 is provided with a diode LD31 and a diode EAM32 which respectively correspond to the PIN structure diodes of the LD and the EAM regions in FIGS. 2A and 2B. The PIN junction diodes of the LD and EAM regions are electrically isolated by the insulating layer 17, and thus the diodes LD31 and EAM32 are connected in parallel to each other. An anode A and a cathode K of the diode LD31 shown in FIG. 3 correspond to the upper cladding layer 14 and the lower cladding layer 12 of the LD region shown in FIGS. 2A, respectively. An anode A and a cathode K of the diode EAM32 shown in FIG. 3 correspond to the upper cladding layer 14 and the lower cladding layer 12 of the EAM region shown in FIGS. 2A, respectively. The anode A and cathode K of the diode LD31 are connected to terminals 33 and 34 corresponding to the anode electrode 20LD and the cathode electrode 21LD, respectively. The anode A and the cathode K of the diode EAM32 are connected to terminals 35 and 36 corresponding to the anode electrode 20EAM and the cathode electrode 21EAM, respectively. The upper insulating layer of the insulating layer 17 which is sandwiched by the upper cladding layer 14 (p-type semiconductive layer) corresponds to a parallel circuit having a resistor 37a and a capacitor 37b in FIG. 3. The lower insulating layer of the insulating layer 17 which is sandwiched by the lower cladding layer 12 (n-type semiconductive layer) corresponds to a parallel circuit having a resistors 38a and a capacitor 38b.

The upper cladding layer 14 and the lower cladding layer 12 sandwich the upper and the lower insulating layers of the insulating layer 17. Each resistance of the resistors 37a and 38a is extremely large and stray capacitance of the capacitors 37b and 38b is extremely small, so that a leak current flowing to the insulating layer 17 and a dielectric polarization of the insulating layer 17 are negligible. Therefore, the insulating layer 17 does not have an influence on the circuit operation.

In the complex optical device element 30, a positive power supply voltage VCC (e.g., +1.7V) is applied to the anode of the diode LD31 through a terminal 33. A terminal 34 of the diode LD31 and a terminal 35 of the diode EAM32 are connected to a ground potential GND. A modulating signal SM (e.g., ±1.0V) superimposed to a bias voltage VB (e.g., +1.5V) is applied to the cathode of the diode EAM32 through a terminal 36. A resistance 41 for matching the impedance is connected across terminals 35 and 36.

When the power supply voltage VCC is applied across the upper cladding layer 14 (p-type semiconductive layer) and the lower cladding layer 12 (n-type semiconductive layer) of the LD region shown in FIGS. 2A and 2B, a laser beam generated in the vicinity of the core layer 13 of the LD region propagates through the core layer 13 along the A1-A2 lines. The laser beam vertically reflects off the upper cladding layer 14 and the lower cladding layers 12 which have a small optical reflectance and laterally reflects off the polyimide layers 16, which are provided in the upper cladding layer 14, having a small optical reflectance. The laser beam confined in the core layer 13 having a large optical reflectance propagates longitudinally along the A1-A2 line shown in FIG. 2A.

It should be noted that the core layer 13 of the isolation region into which a light element ion such as a proton and a boron ion etc. is injected to form the insulating layer 17 does not have an effect on the propagation of the laser beam. In other words, optical properties such as a reflectance etc. of the core layer 13 of the isolation region are not affected by the injection of a light element ion such as a proton and a boron ion etc.

The laser beam propagated to the core layer 13 of the EAM potion through the isolation region is modulated in strength by a PIN junction of the EAM region whose optical reflectance strongly depends on a reverse bias voltage applied thereto. Under a small bias voltage applied across the PIN junction of the EAM region, for instance, −0.5 volts, the laser beam is emitted to the outside of the device without absorption in the PIN junction of the EAM region. Under a large bias voltage applied across the PIN junction of the EAM region, for instance, −2.5 volts, the laser beam is substantially absorbed in the PIN junction of the EAM region without emission.

As mentioned above, the complex optical of the first embodiment includes the EAM and the LD which are optically coupled and electrically isolated from each other on the semiconductor substrate 11. Anodes A and cathodes K of the diode LD31 and the diode EAM32 can be represented as the terminals 33-36 which are electrically isolated from each other. The cathode K of the diode LD31 and the anode A of the diode EAM32 can be connected to the ground potential GND, so that the positive power supply voltage VCC can be applied to the anode A of the diode LD31, and the modulating signal SM biased by a positive voltage VB can be supplied to the cathode K of the diode EAM32.

The first embodiment of the present invention has an advantage of generating a laser light having a high quality waveform because the ground potential GND, which is a reference potential, is not affected by fluctuation of the modulating signal SM. There is another advantage that power consumption can be decreased because a maximum power supply voltage. of the power circuit can be lowered, that is, the maximum voltage necessary for the power-supply voltage and the modulated voltage is +2.5 mvolts.

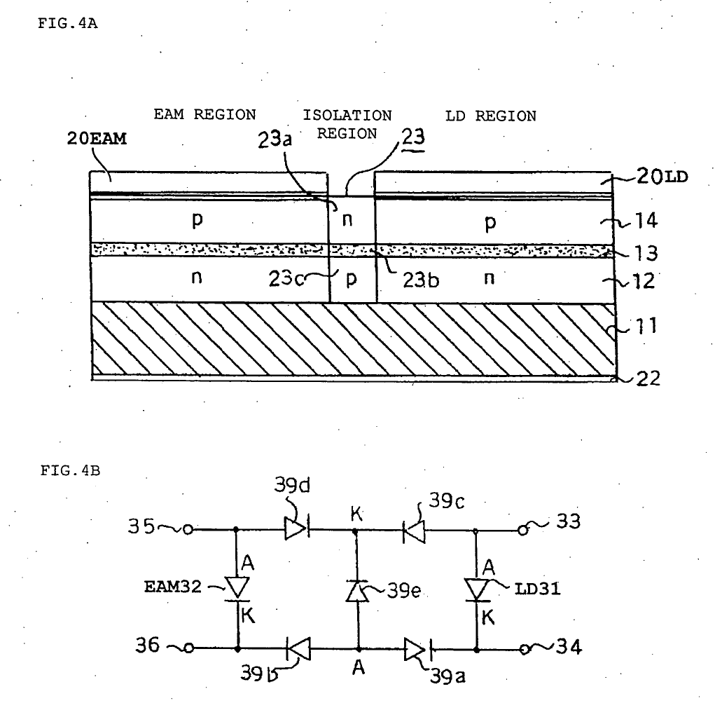

FIG. 4A is a cross-sectional view showing a complex optical device according to a second embodiment of the present invention. FIG. 4B is an equivalent circuit diagram showing the complex optical device of FIG. 4A. The equivalent circuit shown in FIG. 4B corresponds to the equivalent circuit 30 of the first embodiment.

As shown in FIG. 4A, the complex optical device is provided with a semiconductor layer 23 instead of the insulating layer 17 of the isolation region in FIGS. 2A, 2B. The semiconductor layer 23 includes a lower p-type semiconductive layer 23c, a core layer 23b, and an upper n-type semiconductive layer 23a. The lower p-type semiconductive layer 23c which is sandwiched by a lower cladding layer 12 of the LD region and the EAM region is composed of an n-type semiconductive compound such as n-type InP. The upper n-type semiconductive layer 23a which is sandwiched by an upper cladding layer 14 of the LD region and the EAM region is composed of p-type semiconductive compound such as a p-type InP. The core layer 13 and the core layer 23 b are composed of InGaAsP. It is to be noted that a width of the semiconductor layer 23 is assumed to be longer than a diffusion length of electrons or holes for the sake of electrical isolation between the LD and EAM regions. A specific width of the semiconductor layer 23 is ten micrometers or more. Other elements or parts are similar to the first embodiment shown in FIG. 2A and 2B.

A method for fabricating the isolation region of the complex optical device of the second embodiment includes the following steps:

In a first step, the semiconductor substrate 11 is prepared. In a second step, the lower cladding layer 12 (n-type semiconductive layer) is formed on the semiconductor substrate 11. In a third step, a p-type impurity ion is injected at a central area of the lower cladding layer 12 so that the lower p-type semiconductive layer 23c, extending from the surface of the lower cladding layer 12 up to the semiconductor substrate 11, is formed. In a fourth step, the core layer 13 is formed on the lower cladding layer 12 and the lower p-type semiconductive layer 23c. In a fifth step, the upper cladding layer 14 (p-type semiconductive layer) is formed on the core layer 13. In a sixth step, an n-type impurity ion is injected at a central area of the upper cladding layer 14 so that the upper n-type semiconductive layer 23a, extending from the surface of the upper cladding layer 14 up to the surface of the core layer 13, is formed. The isolation region including the upper p-type semiconductive layer 23a and the lower n-type semiconductive layer 23c which sandwich the core layer 23b is formed, thus forming the LD region and EAM region both of which sandwich the isolation region.

The complex optical device shown in FIG. 4A can be represented as an equivalent circuit of FIG. 4B.

The PIN junctions of the LD and the EAM regions correspond to a diode LD31 and a diode EAM32 in the equivalent circuit of FIG. 4B, respectively. The upper cladding layer 14 and the lower cladding layer 12 of the LD region shown in FIG. 4A correspond to an anode A and a cathode K of a diode LD 31 denoted in FIG. 4B, respectively. The upper cladding layer 14 and the lower cladding layer 12 of the EAM region correspond to an anode A and a cathode K of the diode EAM32, respectively.

A PN junction formed from the lower p-type semiconductive layer 23c and the lower cladding layer 12 (n-type semiconductive layer) of the EAM region show in FIG. 4A corresponds to a diode 39a of the equivalent circuit shown in FIG. 4B. A PN junction formed from the lower p-type semiconductive layer 23c and the lower cladding layer 12 (n-type semiconductive layer) of the EAM region corresponds to a diode 39b. The two diodes 39a and 39b, whose forward directions are opposite to each other, are connected in series with each other. A PN junction formed from the upper cladding layer 14 (p-type semiconductive layer) of the LD region and the upper n-type semiconductive layer 23a of the semiconductive layer 23 corresponds to a diode 39c. A PN junction formed from the upper cladding layer 14 (p-type semiconductive layer) of the EAM region and the upper n-type semiconductive layer 23a corresponds to a diode 39d. The two diodes 39c and 39d, whose forward directions are opposite to each other, are connected in series with each other. A PIN junction formed from the lower p-type semiconductive layer 23c, the core layer 23b, and the upper n-type semiconductive layer 23a corresponds to a diode 39e. An anode of the diode 39e is connected to anodes of the diodes 39a and 39b. A cathode of the diode 39e is connected to cathodes of the diodes 39c and 39d.

The equivalent circuit shown in FIG. 4B can be replaced with the complex optical device 30 surrounded by the dashed frame of FIG. 3 (not shown). The terminals 34 to 36 can be connected to the power supply circuit similar to that of the first embodiment in FIG. 3. A positive power supply voltage VCC is applied to the anode of the diode LD31 through the terminal 33. The terminals 34 and 35 are connected to a ground potential. A modulating signal SM superimposed on a bias voltage VB is applied to the cathode of the diode EAM32 through the terminal 36.

The anode A and the cathode K of the diode LD31 are substantially completely electrically isolated from the anode A and the cathode K of the. diode EAM32, so that the complex optical device of the second embodiment has electrical properties similar to that of the first embodiment illustrated in FIG. 2A and 2B.

As mentioned above, the complex optical device of the second embodiment is provided with the, semiconductor layer 23 including the upper n-type semiconductive layer 23a whose conductive type is opposite to a conductive type of the upper cladding layer 14 (p-type semiconductive layer) and the lower p-type semiconductive layer 23c whose conductive type is opposite to a conductive type of the lower cladding layer 12 (n-type semiconductive layer). The LD and EAM regions are electrically isolated from each other, so that the second embodiment of the present invention has an advantage of low power consumption and a generation of a light having a high quality waveform.

The present invention is not to be limited to the embodiments given above, but rather may be modified as follows:
(a) The present invention can be applied to a semiconductor optical amplifier and a semiconductor wavelength converter etc. except for the LD that operates by the forward bias voltage.
(b) The present invention can be applied to an optical modulator operated by another principle, a photodiode, a semiconductor optical switch, and a semiconductor optical directional coupler etc., except for the EAM that operates by the reverse bias voltage.
(c) The complex optical device 30 in FIG. 3 is provided with four terminals 33 to 36. The cathode K of the diode LD31 and anode A of diode EAM32 which are separately connected to the terminals 34 and 35, respectively. By connecting the terminals 34 and 35 with one terminal, the complex optical device 30 in FIG. 3 may be provided with three terminals,
(d) Structures and materials, etc. according to the first and second embodiments are not limited to such that shown in FIGS. 2A, 4A. The lower cladding layer 12 (n-type semiconductive layer) and the upper cladding layer 14 (p-type semiconductive layer) may be replaced with p-type and n-type semiconductive layers, respectively. The first and the second embodiments are fabricated from InGaAsP/InP PIN junction. Other semiconductive compounds, for example, III-IV group semiconductor compounds such as a GaAlAs/GaAs, a InGaAlAs/InP, and a InGaAs/GaAs etc. may be used in the fabrication of the PIN junction.

According to the present invention, methods 1) to 3) are provided for manufacturing a complex optical device. The methods 1) to 3) comprise:
1) preparing a semiconductor substrate,

forming a first semiconductive layer having a first conductive type on said semiconductor substrate,

forming an optical core layer on said first semiconductive layer,

forming a second semiconductive layer having a second conductive type opposite to that of said first semiconductive layer on said core layer, and

performing an ion injection at a central area of said second semiconductive layer so that an insulating layer extending through said core layer from the surface of said second semiconductive layer up to said semiconductor substrate thereby to form a laser emitting element and an optical modulation element both of which sandwich said insulating layer is formed.
2) preparing a semiconductor substrate,

forming a first semiconductive layer having a first conductive type on said semiconductor substrate,

forming an optical core layer on said first semiconductive layer,

performing an ion injection at a central area of said core layer so that a first insulating layer extending through said core layer from the surface of said first semiconductive layer up to said semiconductor substrate is formed,

forming a second semiconductive layer having a second conductive type opposite to that of said first semiconductive layer on said core layer, and

performing an ion injection at a central area of said second semiconductive layer so that a second insulating layer extending from the surface of said second semiconductive layer up to the surface of said core layer thereby to form a laser emitting element and an optical modulation element both of which sandwich an insulating region including said first insulating layer and said second insulating layer is formed.
3) preparing a semiconductor substrate, forming a first semiconductive layer having a first conductive type on said semiconductor substrate,

injecting an impurity ion having second conductive type at a central area of said first semiconductive so that a lower semiconductive layer having said second conductive type opposite to that of said first semiconductive layer extending from the surface of said first semiconductive layer up to said semiconductor substrate is formed,

forming an optical core layer on said first semiconductive layer and said lower semiconductive layer,

forming a second semiconductive layer having said second conductive type opposite to that of said first semiconductive layer on said core layer, and

injecting an impurity ion having said first conductive type at a central area of said second semicondudtive layer so that an upper semiconductive layer having said first conductive type extending from the surface of said second semiconductive layer up to the surface of said core layer thereby to form a laser. emitting element and an optical modulation element both of which sandwich said upper semiconductive layer and said lower semiconductive layer is formed.

This application is based on Japanese Patent Application No. 2005-351804 which is hereby incorporated by reference.

What is claim is:

1. A complex optical device having a laser emitting element and a laser modulation element, which are formed on a substrate and optically coupled with each other, said complex optical device comprising:
an electrical insulating layer formed between said laser emitting element and said laser modulation element,
wherein
said laser emitting element has a first core layer and a first and a second semiconductive layer, both of which sandwich said first core layer, and
said laser modulation element has a second core layer continuous to said first core layer via an intermediate core layer extending through said electrical insulating layer and a third and a fourth semiconductive layer, both of which sandwich said second core layer.

2. A complex optical device according to claim 1,
wherein
said first semiconductive layer and said second semiconductive layer are contiguous to said third semiconductive layer and said fourth semiconductive layer, respectively and
said electrical insulating layer is formed by an ion injection at junctions between said first and said third semiconductive layers and between said second and fourth semiconductive layers.

3. A complex optical device according to claim 2,
wherein said ion injection is additionally injected into said intermediate core layer.

4. A complex optical device according to claim 2,
wherein said ion injection is a proton injection.

5. A complex optical device according to claim 1,
wherein
said first and said third semiconductive layers have a first conductive type,
said second and said fourth semiconductive layers have a second conductive type opposite to said first conductive type, and
said electrical insulating layer including a first insulating layer having said second conductive type which is sandwiched between said first and said third semiconductive layers and a second insulating layer having said first conductive type which is sandwiched by said second and said third semiconductive layers.
